(19) United States
(12) Patent Application Publication
(10) Pub. No.: US 2026/0114328 A1
(43) Pub. Date: Apr. 23, 2026

(54) SEMICONDUCTOR STRUCTURE AND MANUFACTURING METHOD THEREFOR

(71) Applicant: CXMT Corporation, Hefei (CN)

(72) Inventors: Kanyu Cao, Hefei (CN); Hongkai Ji, Hefei (CN)

(73) Assignee: CXMT Corporation, Hefei (CN)

(21) Appl. No.: 19/399,588

(22) Filed: Nov. 24, 2025

Related U.S. Application Data
(63) Continuation of application No. PCT/CN2025/091382, filed on Apr. 27, 2025.

(30) Foreign Application Priority Data
Oct. 17, 2024 (CN) 202411454625.5

(51) Int. Cl. H01L 25/00; H01L 21/56; H01L 23/00; H01L 23/31; H01L 25/065; H01L 25/18

(52) U.S. Cl. CPC H10W 90/00; H10W 74/01; H10W 74/134; H10W 80/161; H10W 80/312; H10W 80/327; H10W 90/297; H10W 90/792

(57) ABSTRACT

Embodiments of the present disclosure provide a semiconductor structure and a manufacturing method therefor. The method includes steps as follows: A first substrate having a central region and an edge region is provided; a first dielectric layer covering the central region and the edge region is formed, where the thickness of the first dielectric layer covering the edge region gradually decreases in a direction away from the central region; a first filling layer of a first dielectric layer covering the edge region is formed; and the first filling layer is planarized, and a first edge region flush with the surface of the first dielectric layer in the central region is formed on the surface of the first filling layer.

### CROSS-REFERENCE TO RELATED APPLICATIONS

The present disclosure is a continuation of International Patent Application No. PCT/CN2025/091382, filed on Apr. 27, 2025, which claims priority of the Chinese Patent Application No. 202411454625.5, filed on Oct. 17, 2024 and entitled “SEMICONDUCTOR STRUCTURE AND MANUFACTURING METHOD THEREFOR”. The above-referenced application is incorporated herein by reference in its entirety.

### TECHNICAL FIELD

Embodiments of the present disclosure relate to the field of semiconductor technologies, and in particular, to a semiconductor structure and a manufacturing method therefor.

### BACKGROUND

With rapid growth of a demand for a data capacity, an increase in degree of integration by increasing packaging density to obtain a higher memory capacity has become an important target of integrated circuit manufacturing at a current stage. In this foreground, a 3D-IC (three-dimensional integrated circuit) technology is widely employed, to stack and bond wafers with the same function or different functions together. The technology has advantages of high-performance, low-cost, and high-integration.

Stacking bonding is an important process in a 3D packaging technology, and is configured to stack multiple wafers or chips in the vertical direction and implement electrical connection. This technology can significantly increase an integration density of chips, shorten a signal transmission path, reduce power consumption, and further reduce a package volume; and is an important technology in fields such as high-performance computing, storage, and mobile devices. In a bonding procedure, the degree of stability between bonded surfaces directly affects the yield of a stacking bonding process. If there is a problem of poor bonding between surfaces bonded to each other, there are risks such as cracking and bonding failure in subsequent thinning or another process.

### SUMMARY

Embodiments of the present disclosure provide a semiconductor structure with a higher degree of integration and a manufacturing method therefor.

A problem to be solved by technical spirits of the present disclosure is not limited to the above-mentioned problem, and a person skilled in the art clearly understands other unmentioned problems from the following description.

Some embodiments of the present disclosure provide a manufacturing method for a semiconductor structure, including the following: A first substrate is provided. The first substrate has a central region and an edge region. A first dielectric layer covering the central region and the edge region is formed. The thickness of the first dielectric layer covering the edge region gradually decreases in a direction away from the central region. A first filling layer covering the first dielectric layer in the edge region is formed. The first filling layer is planarized, and a first edge region flush with the surface of the first dielectric layer in the central region is formed on the surface of the first filling layer.

The manufacturing method for a semiconductor structure provided in some embodiments of the present disclosure further includes the following: A second substrate is provided, where the second substrate has a central region and an edge region. A second dielectric layer covering the central region and the edge region is formed on the second substrate, where the thickness of the second dielectric layer covering the edge region gradually decreases in a direction away from the central region. A second filling layer covering the second dielectric layer is formed on the edge region. The second filling layer is planarized, and a second edge region flush with the surface of the second dielectric layer in the central region is formed on the surface of the second filling layer. The second substrate is aligned with and bonded to the first substrate, so that the central region of the first substrate is bonded to the central region of the second substrate, and the first edge region is bonded to the second edge region.

The manufacturing method for a semiconductor structure provided in some embodiments of the present disclosure further includes the following: First edge trimming is performed on the first substrate and the second substrate bonded to each other, to remove a part of the edge region of the first substrate and a part of the edge region of the second substrate, and remove a part of the first edge region and a part of the second edge region. The first substrate is thinned to form a first bonded structure.

The manufacturing method for a semiconductor structure provided in some embodiments of the present disclosure further includes the following: Multiple first bonded structures are bonded to each other to form a second bonded structure.

In the manufacturing method for a semiconductor structure provided in some embodiments of the present disclosure, before the multiple first bonded structures are bonded to each other to form the second bonded structure, and after the first substrate is thinned, the following is further included: A first bonding surface is formed on the surface of the thinned first substrate. Steps of forming the first bonding surface include the following: A third dielectric layer covering the central region and the edge region is deposited on the surface of the thinned first substrate, where the thickness of the third dielectric layer gradually decreases in the direction away from the central region. A third filling layer is deposited on the third dielectric layer in the edge region, the third filling layer is planarized, and a third edge region flush with the surface of the third dielectric layer in the central region is formed on the surface of the third filling layer. That multiple first bonded structures are bonded to each other to form a second bonded structure includes the following: Central regions of the multiple first bonded structures are bonded to each other, and third edge regions of the multiple first bonded structures are bonded to each other.

The manufacturing method for a semiconductor structure provided in some embodiments of the present disclosure further includes the following: Second edge trimming is performed on the second bonded structure to remove a part of the edge region that is in each of the first bonded structures and that is of the second substrate retained after the first edge trimming and a part of the third edge region, where the width of the edge region of the second substrate removed in the first edge trimming is the same as the width of the edge region of the second substrate removed in the second edge trimming.

In the manufacturing method for a semiconductor structure provided in some embodiments of the present disclosure, after the central regions of the multiple first bonded structures are bonded to each other, and the third edge regions of the multiple first bonded structures are bonded to each other, the following is further included: The second substrate is thinned to form the second bonded structure.

The manufacturing method for a semiconductor structure provided in some embodiments of the present disclosure further includes the following: A third substrate is provided, where the third substrate has a central region and an edge region; a fourth dielectric layer covering the central region and the edge region is formed, where the thickness of the fourth dielectric layer covering the edge region gradually decreases in a direction away from the central region; a fourth filling layer covering the fourth dielectric layer in the edge region is formed; the fourth filling layer is planarized, and a fourth edge region flush with the surface of the fourth dielectric layer in the central region is formed on the surface of the fourth filling layer; a second bonding surface is formed on the surface of the thinned second bonded structure; and the third substrate is aligned with and bonded to the second bonded structure, so that the central region of the third substrate and the fourth edge region are bonded to the second bonding surface.

In the manufacturing method for a semiconductor structure provided in some embodiments of the present disclosure, after the second substrate is aligned with and bonded to the first substrate, the following is further included: A first bonding layer is filled between the first substrate and the second substrate, where the first bonding layer covers at least the first dielectric layer, the second dielectric layer, and unbonded surfaces of the first filling layer and the second filling layer.

In the manufacturing method for a semiconductor structure provided in some embodiments of the present disclosure, after the first bonding layer is formed, the first substrate is thinned to form a first bonded structure.

The manufacturing method for a semiconductor structure provided in some embodiments of the present disclosure further includes the following: Multiple first bonded structures are bonded to each other to form a second bonded structure.

In the manufacturing method for a semiconductor structure provided in some embodiments of the present disclosure, before the multiple first bonded structures are bonded to each other to form the second bonded structure, and after the first substrate is thinned, the following is further included: A first bonding surface is formed on the surface of the thinned first substrate, and steps of forming the first bonding surface include the following: A third dielectric layer covering the central region and the edge region is deposited on the surface of the thinned first substrate, where the thickness of the third dielectric layer gradually decreases in the direction away from the central region; and a third filling layer is deposited on the third dielectric layer in the edge region, the third filling layer is planarized, and a third edge region flush with the surface of the third dielectric layer in the central region is formed on the surface of the third filling layer; and that multiple first bonded structures are bonded to each other to form a second bonded structure includes the following: Central regions of the multiple first bonded structures are bonded to each other, and third edge regions of the multiple first bonded structures are bonded to each other.

In the manufacturing method for a semiconductor structure provided in some embodiments of the present disclosure, after the central regions of the multiple first bonded structures are bonded to each other and the third edge regions of the multiple first bonded structures are bonded to each other, a second bonding layer is filled between the first bonded structures.

In the manufacturing method for a semiconductor structure provided in some embodiments of the present disclosure, after the first dielectric layer covering the central region and the edge region is formed, and before the first filling layer covering the first dielectric layer in the edge region is formed, the manufacturing method further includes the following: First bond pads are formed in the first dielectric layer in the central region; and the first dielectric layer is planarized after the first bond pads are formed, so that the surface of each of the first bond pads is flush with the surface of the first dielectric layer.

In the manufacturing method for a semiconductor structure provided in some embodiments of the present disclosure, after the first edge region is formed, the manufacturing method further includes the following: First bond pads are formed in the first dielectric layer, where the surface of each of the first bond pads is flush with the surface of the first dielectric layer.

Some embodiments of the present disclosure further provide a semiconductor structure, including the following: a first substrate, where the first substrate has a central region and an edge region; a first dielectric layer, where the first dielectric layer covers the central region and the edge region, and the thickness of the first dielectric layer covering the edge region gradually decreases in a direction away from the central region; and a first filling layer, where the first filling layer is formed above the first dielectric layer in the edge region, and the surface of the first filling layer is flush with the surface of the first dielectric layer in the central region.

The semiconductor structure provided in some embodiments of the present disclosure further includes the following: a second substrate, where the second substrate has a central region and an edge region; a second dielectric layer, where the second dielectric layer covers the central region and the edge region of the second substrate, and the thickness of the second dielectric layer covering the edge region gradually decreases in a direction away from the central region; and a second filling layer, where the second filling layer is formed above the second dielectric layer in the edge region, and the surface of the second filling layer is flush with the surface of the second dielectric layer in the central region; and the first dielectric layer in the central region of the first substrate is aligned with and bonded to the second dielectric layer in the central region of the second substrate, and the first filling layer is aligned with and bonded to the second filling layer.

The semiconductor structure provided in some embodiments of the present disclosure further includes the following: a first bonding layer, where the first bonding layer is disposed between the first substrate and the second substrate bonded to each other, and the first bonding layer covers at least unbonded surfaces of the first filling layer and the second filling layer.

In the semiconductor structure provided in some embodiments of the present disclosure, the maximum radial distance from the central region to the center of the central region is R1, the maximum radial distance from the first filling layer to the center of the central region is R2, the maximum radial distance from the first bonding layer to the center of the central region is R3, and the difference between R2 and R1 is greater than the difference between R3 and R2.

### BRIEF DESCRIPTION OF DRAWINGS

The accompanying drawings herein, which are incorporated in and constitute a part of the specification, illustrate embodiments consistent with the embodiments of the present disclosure, and serve to explain the principles of the embodiments of the present disclosure together with the specification.

FIG. 1 is a schematic flowchart of a manufacturing method for a semiconductor structure according to an embodiment of the present disclosure; FIG. 2 to FIG. 10 are cross-sectional views of semiconductor structures according to embodiments of the present disclosure; FIG. 11 is a schematic flowchart of a manufacturing method for a semiconductor structure according to an embodiment of the present disclosure; FIG. 12 to FIG. 18 are cross-sectional views of semiconductor structures according to embodiments of the present disclosure; FIG. 19 is a schematic flowchart of a manufacturing method for a semiconductor structure according to an embodiment of the present disclosure; FIG. 20 to FIG. 22 are cross-sectional views of semiconductor structures according to embodiments of the present disclosure; and FIG. 23 is a cross-sectional top view of a semiconductor structure according to an embodiment of the present disclosure.

The accompanying drawings have already shown clear embodiments of the present disclosure, which are described in more detail below. These accompanying drawings and text descriptions are not intended to limit the scope of the concept of the embodiments of the present disclosure in any manner, but to describe the concept of the embodiments of the present disclosure for a person skilled in the art with reference to specific embodiments.

### DESCRIPTION OF EMBODIMENTS

The technical solutions in the embodiments of the present disclosure are clearly described below with reference to the accompanying drawings in the embodiments of the present disclosure. It may be understood that specific embodiments described herein are merely intended to explain related disclosures, but are not intended to limit the present disclosure. In addition, it should be further noted that for ease of description, only related parts are shown in the accompanying drawings. Unless otherwise defined, all technical and scientific terms adopted in this specification have meanings the same as those commonly understood by a person skilled in the technical field of the present disclosure. The terms adopted in this specification are merely intended to describe the embodiments of the present disclosure, but are not intended to limit the present disclosure. The following descriptions relate to “some embodiments” describing a subset of all possible embodiments. However, it may be understood that “some embodiments” may be the same subset or different subsets of all the possible embodiments, and may be combined with each other when there is no conflict. It should be noted that the term “first\second\third” in the embodiments of the present disclosure is merely intended to distinguish between similar objects, and does not represent specific sorting for the objects. It may be understood that “first\second\third” may be interchanged for a specific sequence or order if allowed, so that the embodiments of the present disclosure described herein can be implemented in a sequence other than those shown or described herein.

The following describes the embodiments of the present disclosure in detail with reference to the accompanying drawings.

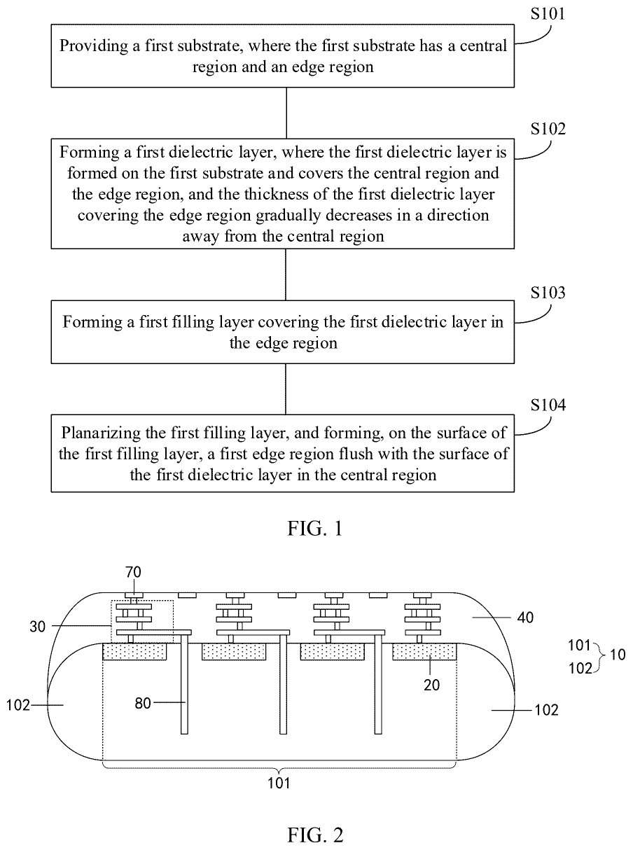

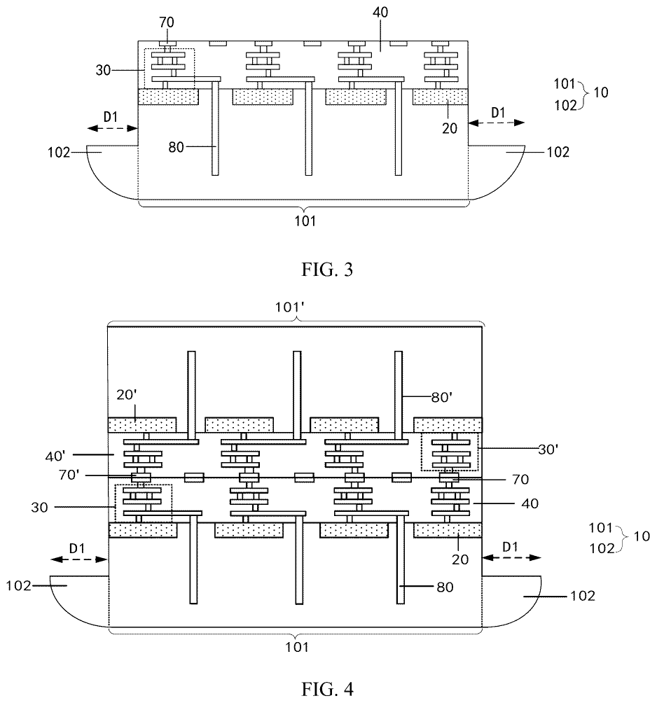

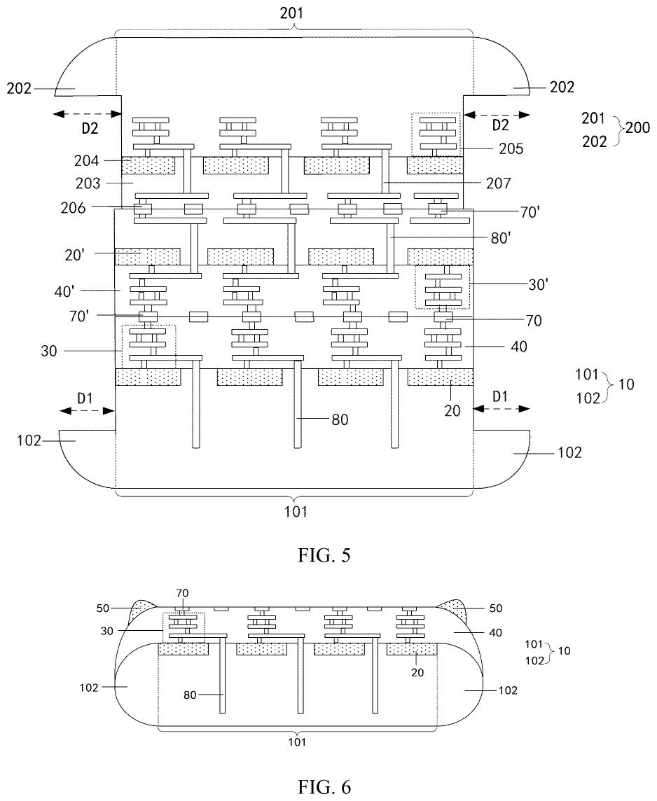

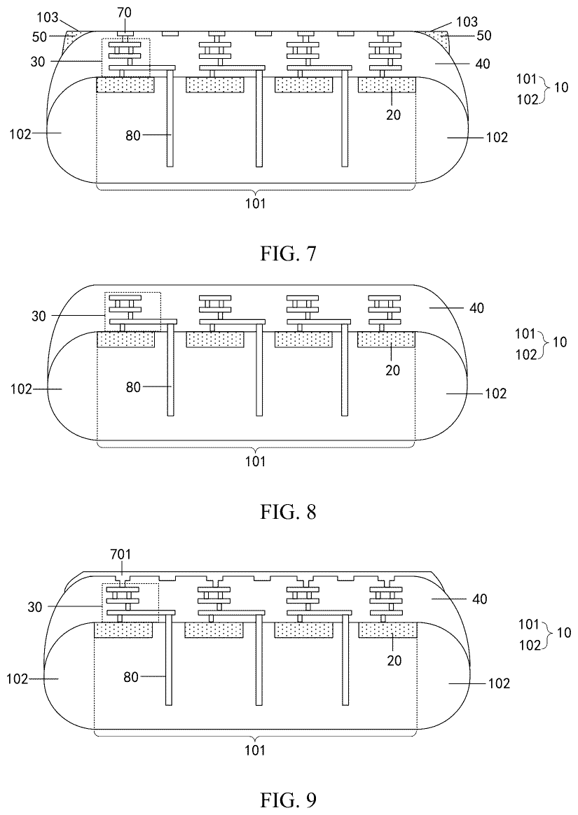

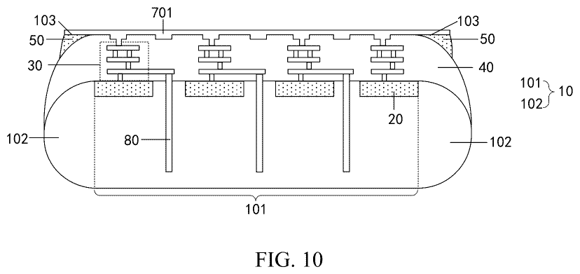

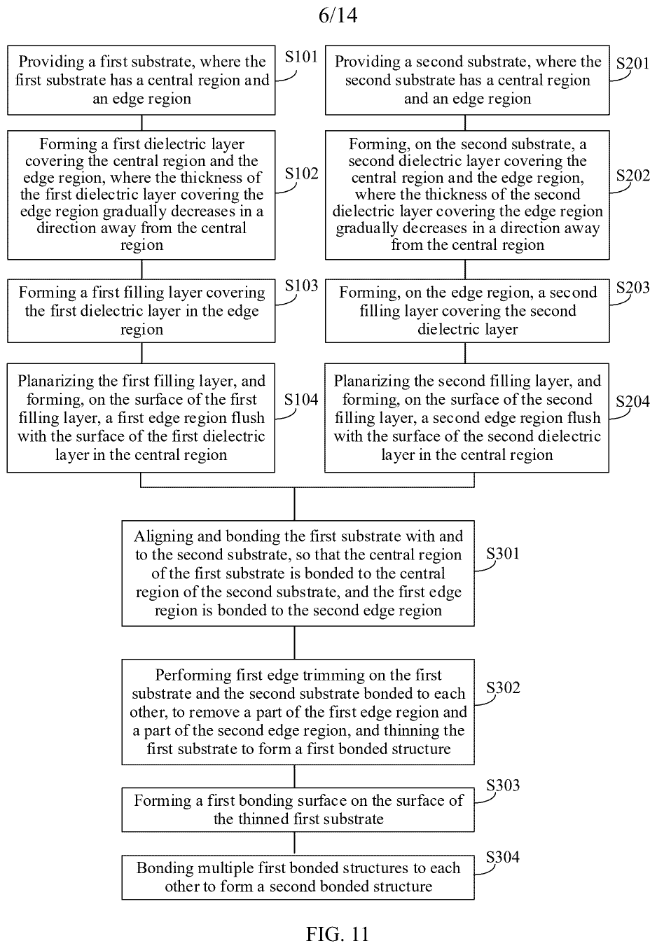

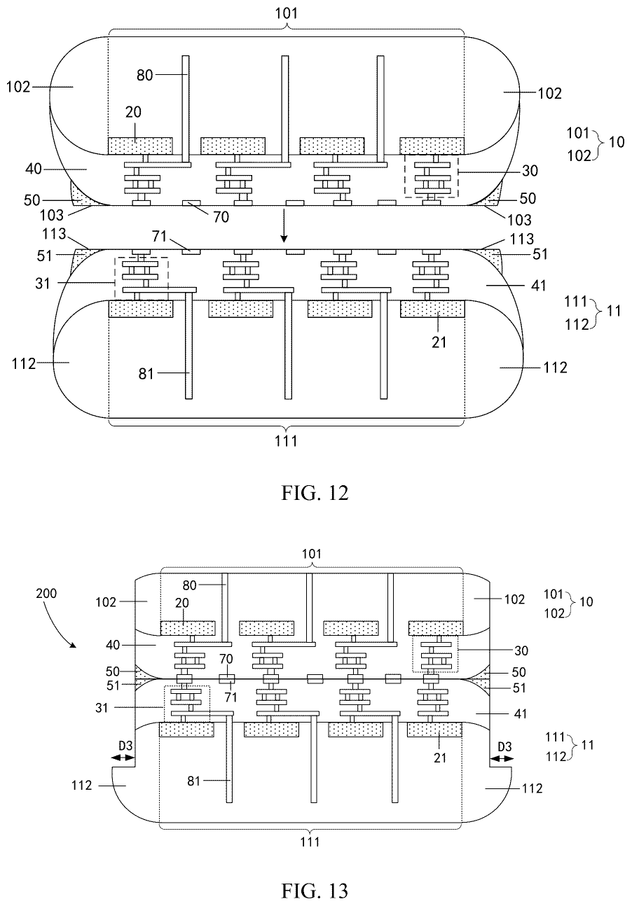

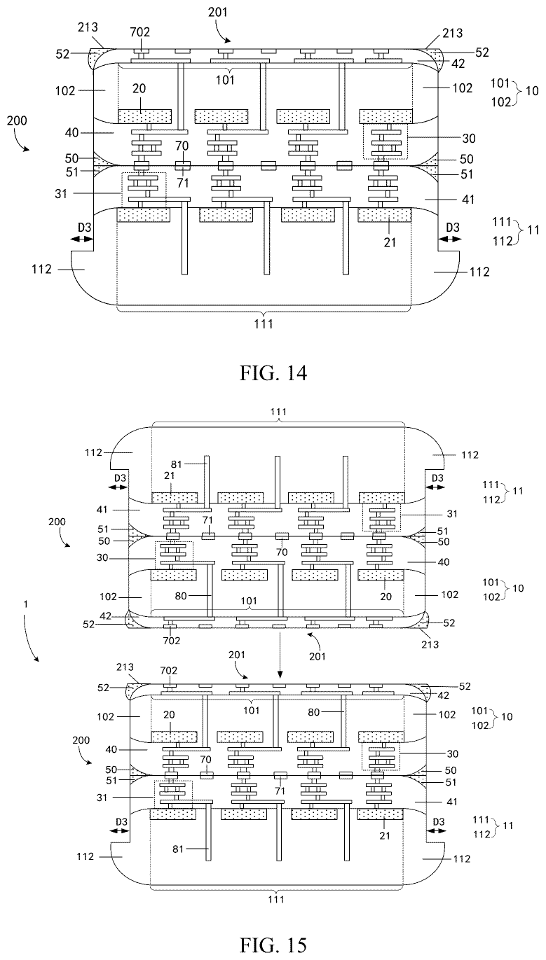

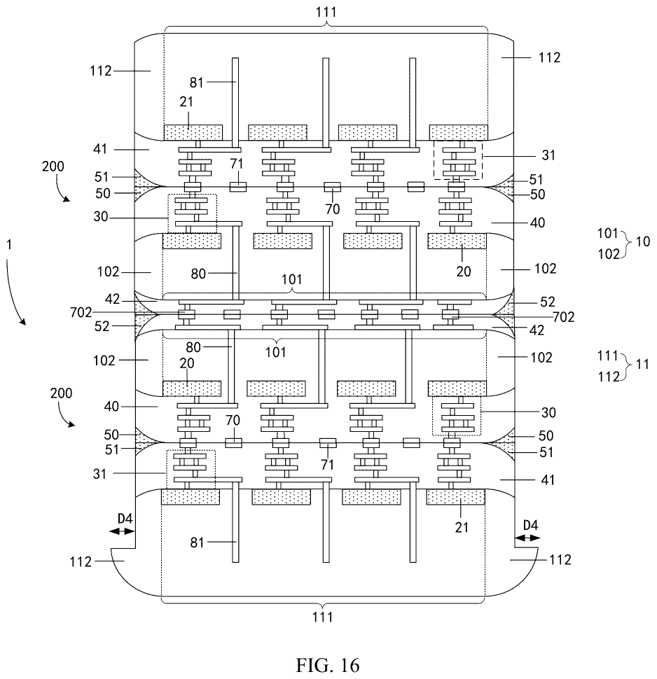

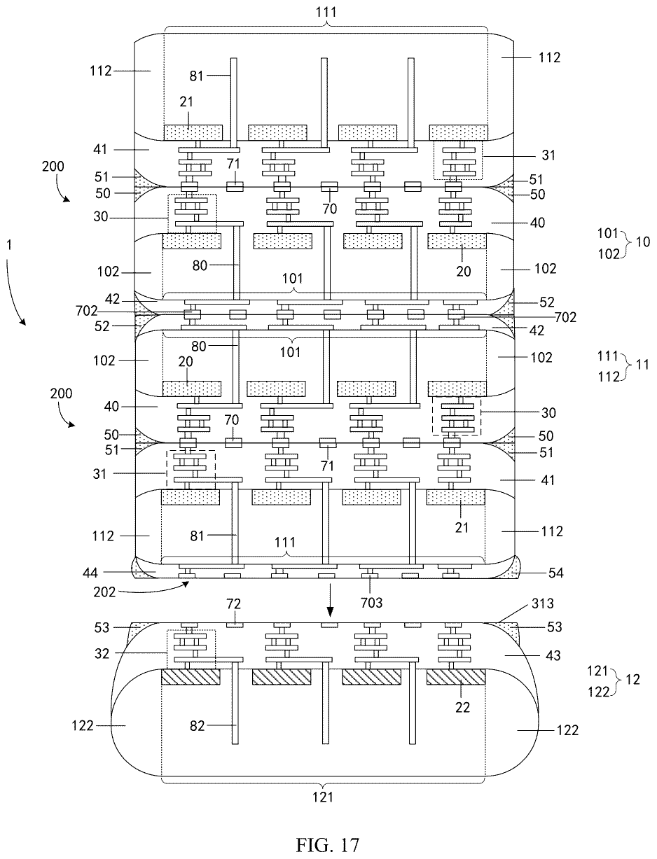

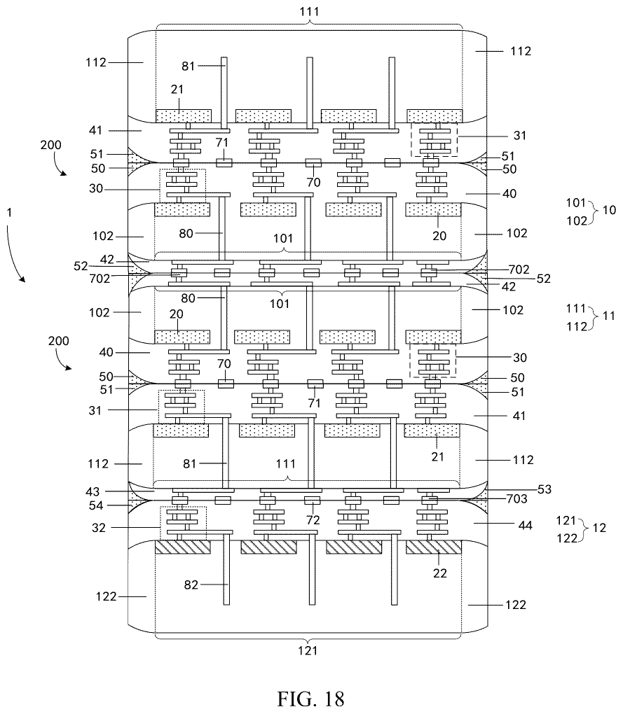

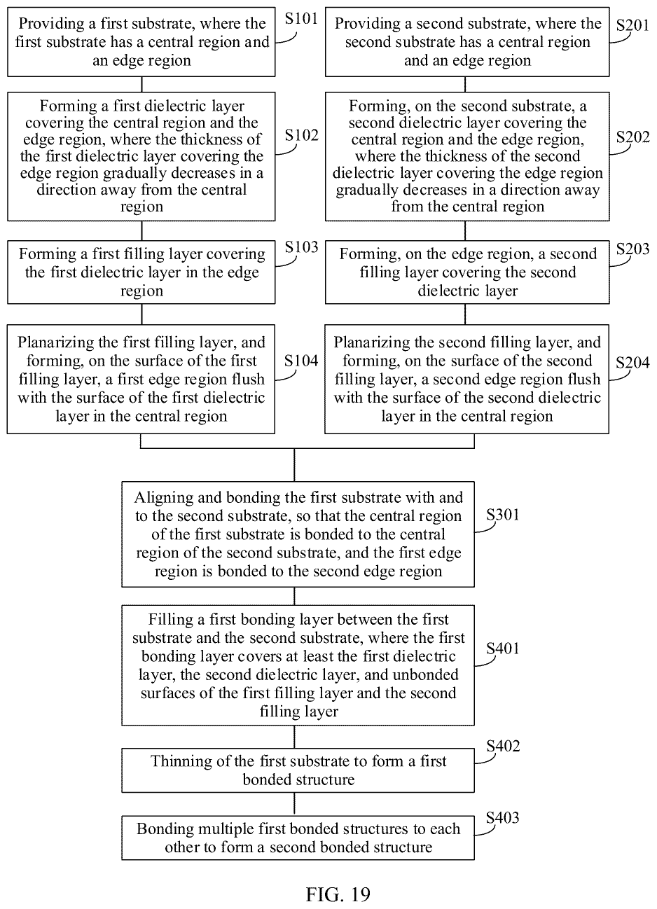

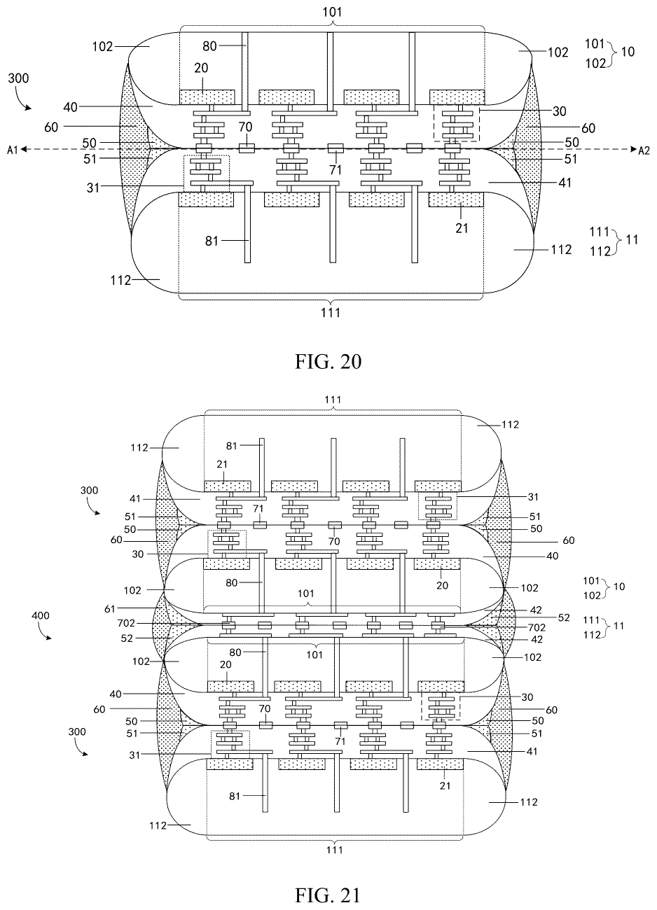

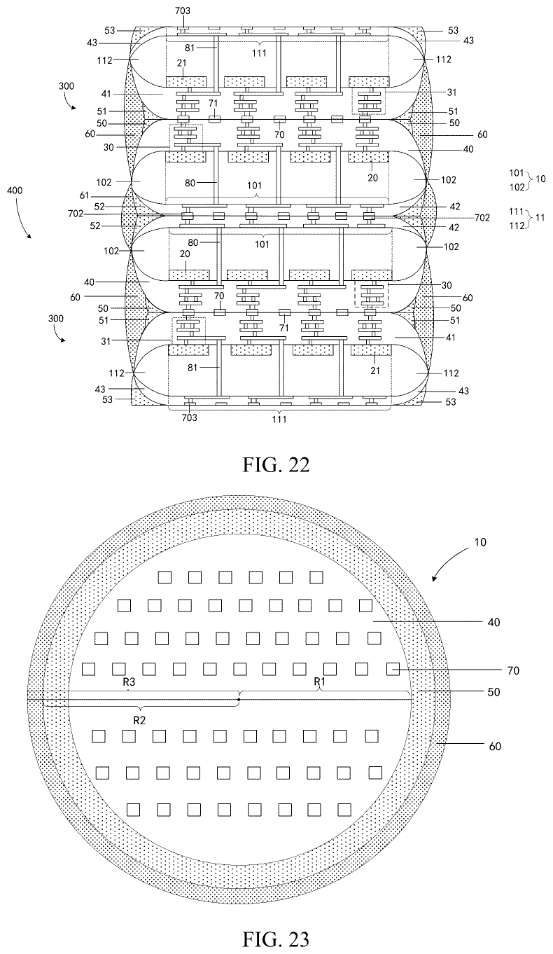

FIG. 1 is a schematic flowchart of a manufacturing method for a semiconductor structure according to an embodiment of the present disclosure. Refer to FIG. 1, the following steps are included. In the step of S101, a first substrate is provided, where the first substrate has a central region and an edge region. Refer to FIG. 2. In this embodiment of the present disclosure, the first substrate may be a substrate of a wafer. As shown in FIG. 2, a first substrate 10 has a central region 101 and an edge region 102, and the edge region 102 is provided around the central region 101. The central region 101 may be a region in which a semiconductor device 20 is disposed in the first substrate 10, and the edge region 102 may be an outer peripheral edge region of the wafer in which the semiconductor device is disposed or not disposed.

The semiconductor device 20 may be a CMOS device, a memory device, and/or another passive device. The memory device may include a volatile memory, a non-volatile memory, or the like, and the volatile memory may include, e.g., a DRAM. In some embodiments, when being a DRAM memory device, the semiconductor device 20 may be a memory element including one transistor and one capacitor, or may be a set of multiple memory elements.

In the step of S102, a first dielectric layer is formed, where the first dielectric layer is formed on the first substrate and covers the central region and the edge region, and the thickness of the first dielectric layer covering the edge region gradually decreases in a direction away from the central region. Still referring to FIG. 2, a first dielectric layer 40 is formed on the first substrate 10, and the first dielectric layer 40 covers the central region 101 and the edge region 102. The central region 101 is further disposed with an interconnection layer 30 electrically connected to the semiconductor device 20, and the interconnection layer 30 is disposed in the first dielectric layer 40. First bond pads 70 are disposed in the first dielectric layer 40, and the first bond pad 70 has a surface exposed to the first dielectric layer 40.

In some embodiments, a procedure of forming the interconnection layer 30 is accompanied by formation of an isolation medium. Therefore, the first dielectric layer 40 may be a dielectric layer formed after the interconnection layer 30 is formed. In this case, the first dielectric layer 40 is formed on the interconnection layer 30.

The interconnection layer 30 may include one or more conductive layers, a through hole connected to each conductive layer, a contact plug connected to the semiconductor device 20, and the like. The material of the interconnection layer 30 may be a metal material, for example, may be tungsten, aluminum, or copper.

The first bond pad 70 may include one or more conductive layers, a through hole connected to each conductive layer, and the like. The material of the first bond pad 70 may be a metal material, for example, may be a metal such as copper, tin, gold, or tungsten, or an alloy thereof.

The first dielectric layer 40 may be a stacked structure formed by an isolation material, including an interlayer dielectric layer, an intermetal dielectric layer, and the like. The isolation material may be a combination of one or more of silicon dioxide, silicon nitride, silicon oxynitride, silicon carbonitride, an L-K dielectric material, and the like, and is configured to provide electrical isolation for each conductive layer, each through hole, each contact plug, and the like in the interconnection layer 30. When the first dielectric layer 40 is located on the interconnection layer 30, the first dielectric layer 40 may be a stacked structure or a single-layer structure formed of an isolation material, and mainly provides isolation for the first bond pad 70 and provides a dielectric surface for bonding.

The first substrate 10 further includes a via interconnection structure 80 running through a part of the first substrate 10, e.g., a TSV. The via interconnection structure 80 is connected to the interconnection layer 30.

The central region 101 of the first substrate 10 has a relatively flat surface, and the edge region 102 is not flat relative to the central region 101, and is a curved surface with some curvature. This is because, when the semiconductor device 20 is prepared, a process such as thin film deposition and photoresist spin coating needs to be performed for multiple times. Because deposition reaction gas, photoresist, or the like is unevenly distributed at the center of the wafer and the edge of the wafer, the thickness of a material in the edge region is different from that in the central region, which may affect the precision of a subsequent process and the performance of the device. In this case, the edge region of the wafer is usually not provided with the same semiconductor device as the central region, and some test structures may be disposed to monitor process quality.

The surfaces of the central region 101 and the edge region 102 of the first substrate 10 are uneven. For the same reason, when the first dielectric layer 40 is formed, the thickness of the first dielectric layer 40 covering the edge region 102 gradually decreases in a direction away from the central region 101.

In some embodiments, the first substrate 10 may be a circular substrate or a wafer, and the direction away from the central region 101 is a radial direction from the center to the edge of the first substrate 10.

In some embodiments, because the surface of the first dielectric layer 40 in the edge region 102 and the surface thereof in the central region 101 are uneven, and such unevenness may affect the yield of the subsequent process. For example, when bonding processing is performed on the first substrate 10 and another substrate or wafer, this edge unevenness may cause an uneven bonding surface. The uneven bonding surface may directly cause a failure of bonding in the edge region 102, forming a bonding smear. This failed bonding is material chipping (Chipping) in an unbonded edge region in the subsequent process, for example, when the first substrate 10 is thinned. To prevent occurrence of such a problem, an edge trimming process may be employed to remove the edge region 102 in a cut manner. As shown in FIG. 3, an edge trimming process is performed on the first substrate 10 and the first dielectric layer 40, to remove the edge region 102 and the first dielectric layer 40, in the edge region 102, having an uneven surface. For example, the edge region 102 whose width is D1 is removed, and only the central region 101 and a corresponding part thereof are retained. Because the central region 101 has a relatively planar surface, the stability of the subsequent process can be ensured.

Although the edge trimming process may eliminate a potential yield problem caused by unevenness of a surface edge region, an entire area of a substrate or a wafer is limited and valuable. A 12-inch wafer is taken as an example. Usually, the diameter of the 12-inch wafer is 300 millimeters (about 11.81 inches), that is, the radius is about 150 millimeters. It is found by the inventors of the present disclosure that when a radial distance varies from 147 millimeters or 147.5 millimeters to 150 millimeters, the thickness difference of the first dielectric layer 40 on the surface of the 12-inch wafer is not less than 2.5 microns. In other words, if an unevenness phenomenon of the edge region is to be eliminated, at least a region of a radial distance of 2.5 millimeters to 3 millimeters needs to be trimmed from the first substrate edge when edge trimming is performed. This means that the effective region area of the first substrate for preparing the semiconductor device becomes small.

In some embodiments, the edge trimming process may occur after bonding of the first substrate 10 and another substrate is completed. As shown in FIG. 4, another substrate has the same or similar structure as the first substrate 10. A semiconductor device 20′ and an interconnection layer 30′ connected to the semiconductor device 20′ are disposed in a first dielectric layer 40′ of another substrate in a central region 101′, first bond pads 70′ are disposed in the first dielectric layer 40′, a via interconnection structure 80′ is disposed in another substrate, and the via interconnection structure 80′ is connected to the interconnection layer 30′.

When the first substrate 10 is bonded to another substrate, the central region 101 is aligned with and bonded to the central region 101′, to implement bonding of the first bond pad 70 and the first bond pad 70′ and bonding of the first dielectric layer 40 and the first dielectric layer 40′. After bonding is completed, an edge region 102′ of another substrate 10′ and the first dielectric layer 40′ located in the edge region 102′ are trimmed by employing the edge trimming process. In addition, the edge region 102 of the first substrate 10 and the first dielectric layer 40 in the edge region 102 are also trimmed, so that a bonding failure region between the edge region 102 and the edge region 102′is removed, and the width of a trimmed region is also D1, thereby reducing a risk of the subsequent process.

In some embodiments, three or more substrates or wafers may be bonded to each other. As shown in FIG. 5, FIG. 5 is a schematic diagram of bonding three semiconductor substrates or wafers to each other. Another substrate 200 is provided, and another substrate 200 has the same or similar structure as the first substrate 10. Another substrate 200 has a central region 201 and an edge region 202, and the central region 201 and the edge region 202 are disposed with a first dielectric layer 203, and a semiconductor device 204 and an interconnection layer 205 connected to the semiconductor device 204 are disposed in the first dielectric layer 203 in the central region 201. First bond pads 206 are disposed in the first dielectric layer 203, and a via interconnection structure 207 is formed in the substrate 200, and is connected to the interconnection layer 205. Before the substrate 10′ is bonded, thinning processing is performed on the another substrate on the first substrate 10, to expose the via interconnection structure 80′, the another bond pad 70′ is formed on the surface of the exposed via interconnection structure 80′, the surface of the thinned another substrate is taken as a bonding surface, and the another bond pad 70′ is bonded to the first bond pad 206 on the surface of the substrate 200. To ensure a bonding effect, before bonding, edge trimming is performed on the substrate 200, and the width of a trimmed region is D2, where D2 is greater than D1. This is because it is difficult to keep the widths of edge trimmed regions of the substrate 200 and the substrate 10 completely consistent. To avoid poor bonding caused by a trimming error, usually, it is necessary to perform more edge trimming on the substrate 200, to ensure that the substrate 200 is well bonded to the surface of another substrate. It may be learned that when multiple substrates or wafers are bonded through stacking, to ensure a bonding effect, an area of a trimmed region of the substrate or the wafer gradually increases, an area of the substrate or the wafer is wasted, a quantity of effective chips on the substrate or the wafer decreases, and production costs increase.

After the interconnection layer 30 and the first dielectric layer 40 are completed, the manufacturing method in this embodiment of the present disclosure further includes the following: In the step of S103, a first filling layer covering the first dielectric layer in the edge region is formed. As shown in FIG. 6, a first filling layer 50 is deposited on the surface of the first dielectric layer 40 in the edge region 102. Forming the first filling layer 50 may be implemented by employing an annular mold. The mold may be an annular ring covering the central region 101. To be specific, the annular ring is employed to cover the central region 101, the edge region 102 is exposed outside the annular ring, and then the first filling layer 50 is formed on the edge region 102 in a manner such as deposition. The first filling layer 50 has a surface higher than the first dielectric layer 40 in the central region 101, that is, the first filling layer 50 has a protruding part relative to the first dielectric layer 40 in the central region 101. The first filling layer 50 may include an oxide, e.g., silicon oxide. In the specification, “silicon oxide” is defined to include a compound containing silicon and oxygen atoms, including any and all stoichiometric possibilities SiₓO_{y} of Si, where x and y may be integers or may be non-integers.

In the step of S104, the first filling layer is planarized, and a first edge region flush with the surface of the first dielectric layer in the central region is formed on the surface of the first filling layer. As shown in FIG. 7, after a first filling layer 50 is formed, a planarization process is performed to planarize the first filling layer 50, and a first edge region 103 is formed on the surface of the first filling layer 50. The first edge region 103 has a surface flush with the first dielectric layer 40 in the central region 101. Due to a limitation of a process condition, “flush” herein may be completely flush, or may be substantially flush. The planarization process may be a chemical mechanical polishing (CMP) process, or may be an etching planarization process. The planarization process may be further performed on the first dielectric layer 40 in the central region 101 for planarization processing, so that the first dielectric layer 40 in the central region 101 and the first filling layer 50 form planar surfaces.

According to the manufacturing method provided in this embodiment of the present disclosure, a planar region of the surface of the obtained semiconductor structure has a larger area, which can effectively improve a problem that an area of an uneven region of the edge region is large, and further increases an effective usage area of the substrate or the wafer. A 12-inch wafer is taken as an example, and an edge region with a radial distance from 147 millimeters or 147.5 millimeters to 150 millimeters has an uneven surface. After the manufacturing method in the foregoing embodiment is adopted for the uneven region, an edge region with the radial distance from 147 millimeters or 147.5 millimeters to 149 millimeters or 149.5 millimeters can obtain a surface flush or relatively flush with the central region, thereby effectively improving the appearance of the edge region.

In some embodiments, after the first dielectric layer covering the central region and the edge region is formed, and before the first filling layer covering the first dielectric layer in the edge region is formed, the method further includes the following: First bond pads are formed in the first dielectric layer in the central region. The following describes in detail a procedure of forming the first bond pad with reference to corresponding accompanying drawings. As shown in FIG. 8, the first dielectric layer 40 covering the central region 101 and the edge region 102 is formed. Still referring to FIG. 9, after the first dielectric layer 40 is formed, the first dielectric layer 40 is patterned, and a first bonding material layer 701 is formed in the first dielectric layer 40 in the central region 101. A procedure of forming the first bonding material layer 701 may adopt a process such as deposition, electroplating, and the like. After the first bonding material layer 701 is formed, the first bonding material layer 701 is planarized. The first bond pads 70 that are isolated from each other and that have surfaces exposed to the first dielectric layer 40 are formed in the first dielectric layer 40. The surface of the first bond pad 70 is flush or substantially flush with the surface of the first dielectric layer 40, as shown in FIG. 2. In some embodiments, a specific height difference exists between the surface of the first bond pad 70 and the surface of the first dielectric layer 40. This case is also considered as a flush case in the present disclosure.

In some embodiments, after the first bond pad 70 is formed, steps of forming the first filling layer 50 on the surface of the first dielectric layer 40 on the edge region 102 of the first substrate 10 and subsequently planarizing the first filling layer 50 to form the first edge region 103 are performed, as shown in FIG. 6 and FIG. 7.

In the method for forming the first bond pad provided in the foregoing embodiment, the first bond pad is formed before the first filling layer is formed, that is, before the first filling layer is formed, a surface planarization process needs to be performed to planarize the first bonding material and the first dielectric layer. After the first filling layer is formed, a planarization process is performed on the surface of the first filling layer.

An embodiment of the present disclosure further provides another method for forming the first bond pad. The following describes in detail a procedure of forming the first bond pad with reference to corresponding accompanying drawings. Referring to FIG. 6 and FIG. 7, the first dielectric layer 40 and the first filling layer 50 are first formed, then, the first filling layer 50 is planarized, and the first edge region 103 flush with the surface of the first dielectric layer 40 in the central region 101 is formed on the surface of the first filling layer 50. In this planarization procedure, the surface of the first dielectric layer 40 in the central region 101 may also be planarized.

Still referring to FIG. 10, after the surfaces of the first dielectric layer 40 and the first filling layer 50 are planarized, and the first edge region 103 is formed, the first dielectric layer 40 is patterned, and the first bonding material layer 701 is formed in the first dielectric layer 40 in the central region 101. A procedure of forming the first bonding material layer 701 may adopt a process such as deposition, electroplating, and the like. After the first bonding material layer 701 is formed, the first bonding material layer 701 is planarized. The first bond pads 70 that are isolated from each other and that have surfaces exposed to the first dielectric layer 40 are formed in the first dielectric layer 40. The surface of the first bond pad 70 is flush or substantially flush with the surface of the first dielectric layer 40, as shown in FIG. 7.

In the method for forming the first bond pad provided in the foregoing embodiment, the first bond pad is formed after surface planarization processing is performed on the first filling layer to make the surface of the first filling layer be substantially flush with the surface of the first dielectric layer. In other words, before the first filling layer is formed, the surface planarization process does not need to be performed on the first dielectric layer, thereby reducing costs of the planarization process. After the first filling layer is formed, the surface planarization process may be performed once, to implement that the surfaces of the first filling layer and the first dielectric layer are substantially flush with each other. After the first bonding material layer is subsequently formed, the surface planarization process is performed again to obtain the first bond pad.

In some embodiments, the first bond pad further includes a part of the first bond pad connected to the interconnection layer and a part of the first bond pad not connected to the interconnection layer. The part of the first bond pad connected to the interconnection layer is configured to implement signal extraction of the interconnection layer, and the part of the first bond pad not connected to the interconnection layer is mainly configured to increase the density of the first bond pad or is disposed for consideration of other bonding performance. In some embodiments, the first bond pads in the present disclosure may be all connected to the interconnection layer without being limited by a structure in the accompanying drawings.

Some other embodiments of the present disclosure further provides a manufacturing method for a semiconductor structure. Specifically, as shown in FIG. 11, FIG. 11 is a schematic flowchart of a manufacturing method for a semiconductor structure according to an embodiment of the present disclosure. The steps are listed below.

In the step of S201, a second substrate is provided, where the second substrate has a central region and an edge region.

In the step of S202, a second dielectric layer covering the central region and the edge region is formed on the second substrate, where the thickness of the second dielectric layer covering the edge region gradually decreases in a direction away from the central region.

In the step of S203, a second filling layer covering the second dielectric layer is formed on the edge region.

In the step of S204, the second filling layer is planarized, and a second edge region flush with the surface of the second dielectric layer in the central region is formed on the surface of the second filling layer.

The second substrate may adopt the same structure and the same manufacturing method as the first substrate. Step S201 to step S204 correspond to step S101 to step S104. Therefore, step S201 to step S204 are not described in detail herein.

For a specific structure of the second substrate, refer to FIG. 12. A second substrate 11 includes a central region 111 and an edge region 112, and the edge region 112 is disposed around the central region 111. A second dielectric layer 41 is formed in both the central region 111 and the edge region 112. The thickness of the second dielectric layer 41 in the edge region 112 gradually decreases in a direction away from the central region 111. A second filling layer 51 is formed on the surface of the second dielectric layer 41 in the edge region 112, and has a second edge region 113 flush with the surface of the second dielectric layer 41 in the central region 111. The materials of the second filling layer 51 and a first filling layer 50 may be the same. A semiconductor device 21 is further disposed in the central region 111, and a semiconductor device may be disposed or not disposed in the edge region 112. The semiconductor device 21 may be a device of the same type as the semiconductor device 20, or may be a device of a different type. The central region 111 further includes an interconnection layer 31 connected to the semiconductor device 21, and the interconnection layer 31 is disposed in the second dielectric layer 41. The interconnection layer 31 may have the same structure and be obtained by employing the same process as an interconnection layer 30. A second bond pad 71 is disposed in the second dielectric layer 41 in the central region 111, and the second bond pad 71 is connected to the interconnection layer 31. The second bond pad 71 may have the same structure and be obtained by employing the same process as a first bond pad 70. The central region 111 of the second substrate 11 further includes a via interconnection structure 81 running through a part of the second substrate 11, and is connected to the interconnection layer 31 through the via interconnection structure 81.

Still referring to FIG. 11 and FIG. 12, after processing of the first substrate and the second substrate is completed, step S301 is performed, that is, the first substrate is aligned with and bonded to the second substrate, so that the central region of the first substrate is bonded to the central region of the second substrate, and the first edge region is bonded to the second edge region.

The central region of the first substrate and the central region of the second substrate may be bonded to each other by employing a medium-medium direct bonding process, or may be bonded to each other by employing a medium-medium metal-metal bonding process. For example, the first bond pad in the central region of the first substrate and the second bond pad in the central region of the second substrate are bonded to each other. The first edge region and the second edge region may be bonded to each other by employing a medium-medium direct bonding process.

Still referring to FIG. 11 and FIG. 13, after the first substrate is bonded to the second substrate, step S302 is performed: First edge trimming is performed on the first substrate and the second substrate bonded to each other, to remove a part of the edge region of the first substrate and a part of the edge region of the second substrate, and the first substrate is thinned to form a first bonded structure. In a first edge trimming procedure, a part of the first edge region and a part of the second edge region are also removed. Finally, a first bonded structure 200 is formed. The width of the first edge trimming is D3, the edge region 102 of the first substrate 10 is partially removed, and a part of the edge region 102 is retained. The first edge region 103 is also partially removed, and a part of the first filling layer 50 is retained. The edge region 112 of the second substrate 11 is also partially removed, and a part of the edge region 112 is retained. The second edge region 113 is also partially removed, and a part of the second filling layer 51 is retained. The retained part of the first filling layer 50 and the retained part of the second filling layer 51 are bonded to each other. In some embodiments, the first edge region 103 and the second edge region 113 may alternatively be all retained. To be specific, the first edge trimming only needs to remove a part of edge regions in the edge region 102 and the edge region 112 other than the first edge region 103 and the second edge region 113. After the first substrate 10 is bonded to the second substrate 11, a part of the first edge region 103 and a part of the second edge region 113 are removed through trimming, thereby further increasing the yield of a bonded edge.

In some embodiments, still referring to FIG. 13, after the first edge trimming is performed, thinning processing is performed on the first substrate, to expose another end of the via interconnection structure 80 in the central region 101 of the first substrate 10, so that the first substrate 10 reaches a predetermined thickness, thereby forming the first bonded structure 200. There are two main thinning processing manners: grinding (Grinding) and chemical mechanical polishing (CMP). Grinding refers to removing a material on a wafer surface in a mechanical manner to achieve a purpose of thinning. Chemical mechanical polishing refers to a finer thinning method that combines chemical reaction and mechanical friction to achieve high-precision thinning and planarization. CMP can provide higher surface quality and more precise thickness control, but a procedure is relatively slow and the costs are also relatively high. The first bonded structure formed by thinning the first substrate may be further employed in a three-dimensional package to obtain a product with a smaller package size and a higher degree of integration.

In some embodiments, after the first bonded structure 200 is formed, the method further includes the following: The first bonded structure 200 is singulated by employing a cutting tool. For example, the first bonded structure 200 is singulated by employing the cutting tool such as a cutting blade or a laser.

Still referring to FIG. 11 and FIG. 14, after the first bonded structure 200 is formed, step S303 is further performed: A first bonding surface is formed on the surface of the thinned first substrate. A specific procedure of forming the first bonding surface is as follows:

As shown in FIG. 14, a third dielectric layer 42 covering the central region 101 and the edge region 102 is formed on the thinned surface of the first substrate 10. The third dielectric layer 42 has a gradually reduced thickness in the direction away from the central region 101. In other words, the thickness of the third dielectric layer 42 above the edge region 102 gradually decreases with increasing of a radial distance. This is because, in a procedure of thinning the first substrate 10, there is a problem that the surface of the edge region 102 is still uneven with the central region 101. Even if the central region 101 and the edge region 102 of the first substrate 10 are flush with each other, after the third dielectric layer 42 is formed, surface planarization processing needs to be performed on the third dielectric layer 42. Likewise, due to a limitation of a process, there is a problem that the thickness of the third dielectric layer 42 in the edge region 102 decreases with increasing of the radial distance. Therefore, after the third dielectric layer 42 is formed, a third filling layer 52 is covered above the third dielectric layer 42 in the edge region 102, and the third filling layer 52 is planarized, so that a third edge region 213 flush with the surface of the third dielectric layer 42 in the central region 101 is formed on the surface of the third filling layer 52 in the edge region 102. A first bonding surface 201 is formed on the surfaces of the third edge region 213 and the third dielectric layer 42 in the central region 101.

The third dielectric layer 42 may have the same composition and be formed by employing the same process as the first dielectric layer 40 and the second dielectric layer 41, and the third filling layer 52 may have the same composition and be formed by employing the same process as the first filling layer 50 and the second filling layer 51.

A procedure of forming the first bonding surface 201 further includes a procedure of forming a third bond pad 702. The third bond pad 702 is formed in the third dielectric layer 42. For formation of the third bond pad 702, refer to the foregoing process procedure of forming the first bond pad 70. Details are not described herein.

Still referring to FIG. 11, FIG. 15, and FIG. 16, after the first bonding surface is formed, step S304 is performed: Multiple first bonded structures are bonded to each other to form a second bonded structure.

As shown in FIG. 15, two first bonded structures 200 are bonded to each other through the first bonding surface 201 to form a second bonded structure 1. To be specific, third dielectric layers 42 in central regions 101 are aligned with and bonded to each other, and third filling layers 52 in third edge regions 213 are bonded to each other. Bonding of the central regions 101 may include medium-medium direct bonding and metal-metal direct bonding, e.g., bonding of third dielectric layers 42 and bonding of third bond pads 702. Bonding of the third edge regions 213 may include a medium-medium direct bonding.

FIG. 15 shows a case in which two first bonded structures are bonded to each other. In some embodiments, more than two first bonded structures may be bonded to each other to form a bonded structure with a higher degree of integration. The bonded structure with the higher degree of integration may be obtained by bonding multiple second bonded structures, or may be obtained by bonding more than two first bonded structures. Regardless of whether more than two first bonded structures are bonded to each other or multiple second bonded structures are bonded to each other, the foregoing steps of performing thinning, forming a third dielectric layer and a third filling layer may be repeated to form a first bonding surface. Details are not described herein. In some embodiments, the bonded structure with the higher degree of integration includes four or more first bonded structures or two or more second bonded structures.

In some embodiments, in step S302, in a procedure of thinning the first substrate, a structure to be bonded in the first substrate is exposed, and after thinning is completed, multiple first bonded structures may be directly bonded, thereby omitting a step of forming the first bonding surface, reducing process costs.

Still referring to FIG. 16, after the two first bonded structures 200 are bonded to each other to form the second bonded structure 1, second edge trimming is performed on the second bonded structure 1, to remove a part of the edge region 112 and a part of the third edge region 213 that are of the second substrate 10 in each first bonded structure 200 and that are retained after the first edge trimming, to complete the second edge trimming. The width of the second edge trimming is D4. In some embodiments, the width D3 of the first edge trimming is the same as the width D4 of the second edge trimming. This is because the first bonding surface extending flatly to the edge region 102 is formed on the surface of each first bonded structure 200, so that the third edge region 213 flush with the third dielectric layer 52 in the central region 101 is formed in the edge region 102 of the first substrate 10 in a manner of forming the third filling layer 52. Therefore, it is ensured that the two first bonded structures can be stably bonded to each other through the first bonding surface. In a second edge trimming procedure, there is no need to remove more edge regions, which prevents a usage area of the substrate or the wafer from being wasted due to edge trimming while ensuring the yield of bonding.

Still referring to FIG. 17, in some embodiments, after the second edge trimming of the second bonded structure 1 is completed, the method further includes the following: The second substrate 11 is thinned, where the second substrate 11 is thinned to a target thickness, and the second bonded structure 1 is finally formed. Thinning of the second substrate 11 means that the via interconnection structure 81 in the second substrate 11 is exposed from the other side of the second substrate 11. FIG. 17 is a schematic structural diagram of a thinned part of the second substrate 11. In some embodiments, all second substrates 11 in the second bonded structure 1 are thinned. In some embodiments, the second substrate 11 is thinned to the same thickness as the first substrate 10.

In some embodiments, after the second bonded structure is formed, multiple second bonded structures may be further bonded to each other to form a bonded structure with a higher degree of integration. Before bonding of each second bonded structure, a bonding surface of each second bonded structure may be formed by employing the same process step as the foregoing forming the first bonding surface, to implement bonding of each second bonded structure. For a specific implementation procedure, details are not described.

In some embodiments, after the second bonded structure 1 is formed, the method further includes the following: The second bonded structure 1 is singulated by employing a cutting tool. For example, the second bonded structure 1 is singulated by employing the cutting tool such as a cutting blade or a laser.

In some embodiments, after the second bonded structure is formed, bonding the third substrate to the second bond is further provided. As shown in FIG. 17, FIG. 17 is a schematic structural diagram of bonding a third substrate to a second bonded structure. The third substrate 12 includes a central region 121 and an edge region 122, and the edge region 122 is disposed around the central region 121. A fourth dielectric layer 43 is formed in the central region 121 and the edge region 122. The thickness of the fourth dielectric layer 43 in the edge region 122 gradually decreases in a direction away from the central region 121. A fourth filling layer 53 is formed on the surface of the fourth dielectric layer 43 in the edge region 122, and has a fourth edge region 313 flush with the surface of the fourth dielectric layer 43 in the central region 121. The materials of the fourth filling layer 53 and the first filling layer 50 may be the same. A semiconductor device 22 is further disposed in the central region 121, and a semiconductor device may be disposed or not disposed in the edge region 122. The semiconductor device 22 may be a device of the same type as the semiconductor device 20, or may be a device of a different type. The semiconductor device 22 shown in FIG. 17 is different from the semiconductor device 20 and the semiconductor device 21. The central region 121 further includes an interconnection layer 32 connected to the semiconductor device 22, and the interconnection layer 32 is disposed in the fourth dielectric layer 43. The interconnection layer 32 may be an interconnection layer including multiple layers of metal lines. A fourth bond pad 72 is disposed in the fourth dielectric layer 43, and the fourth bond pad 72 is connected to or not connected to the interconnection layer 32. A via interconnection structure 82 running through a part of the third substrate 12 is disposed in the central region 121 of the third substrate 12, and the via interconnection structure 82 is connected to the interconnection layer 32.

The third substrate 12 has the same structural feature as the first substrate 10 and the second substrate 11. A method for forming the fourth dielectric layer 43, the fourth filling layer 53, and the fourth edge region 313 is the same as the method for forming each filling layer on the surfaces of the first substrate 10 and the second substrate 11 and each edge region in the foregoing embodiments. The fourth bond pad 72 and the first bond pad 70 have the same forming method. Details are not described herein.

Still referring to FIG. 17, after the second substrate 11 in the second bonded structure is thinned, a second bonding surface 202 is formed on the surface of the thinned second substrate 11. For a method for forming the second bonding surface 202, reference may be made to a method for forming the first bonding surface 201 shown in FIG. 11. The second bonding surface 202 includes the surface of a fifth dielectric layer 44 located in the central region 111 of the second substrate 11, the surface of a fifth filling layer 54 located in the edge region 112 of the second substrate 11, and a fifth bond pad 703 located in the fifth dielectric layer 44. The fifth bond pad 703 is connected to the via interconnection structure 81 in the central region 111 of the second substrate 11. A structure and a formation method of the fifth bond pad 703 are the same as those of the third bond pad 702. Details are not described herein.

After the second bonded structure 1 is bonded to the third substrate 12, third edge trimming is performed to finally obtain a semiconductor structure shown in FIG. 18. A part of the edge region 122 of the third substrate 12 and a part that is of the second bonding surface 202 of the second bonded structure 1 and that is incompletely bonded to the fourth edge region on the third substrate 12 are cut off when the third edge trimming is performed. The width of the third edge trimming is the same as the width of the first edge trimming and the width of the second edge trimming.

In some embodiments, each semiconductor device in the second bonded structure 1 is a memory device, e.g., a DRAM, and a semiconductor device in the third substrate 12 is a logic device.

In some embodiments, after the second bonded structure is bonded to the third substrate, the method further includes the following: A bonded structure formed by the second bonded structure and the third substrate is singulated by employing a cutting tool. For example, monolithic processing is performed by employing the cutting tool such as a cutting blade or a laser.

An embodiment of the present disclosure further provides a schematic flowchart of another manufacturing method for a semiconductor structure. Referring to FIG. 11 and FIG. 19, after the first substrate is aligned with and bonded to the second substrate, that is, after step S301, step S401 is performed on the first substrate and the second substrate bonded to each other.

In the step of S401, a first bonding layer is filled between the first substrate and the second substrate, where the first bonding layer covers at least the first dielectric layer, the second dielectric layer, and unbonded surfaces of the first filling layer and the second filling layer. As shown in FIG. 20, FIG. 20 is a schematic structural diagram of the first substrate 10 and the second substrate 11 in FIG. 12 after bonding is completed. A first bonding layer 60 is formed between the first substrate 10 and the second substrate 11. Specifically, the first bonding layer 60 is formed in a gap between the first substrate 10 and the second substrate 11 bonded to each other, and covers at least the first dielectric layer 40, the second dielectric layer 41, and unbonded surfaces of the first filling layer 50 and the second filling layer 51. When the first filling layer 50 is formed, an outer surface of a part of the first dielectric layer 40 in the edge region 102 of the first substrate 10 is incompletely covered by the first filling layer 50. In this case, the outer surface of the part of the first dielectric layer 40 in the edge region 102 of the first substrate 10 after bonding and the unbonded surface of the first filling layer 50 are exposed. Similarly, after the second filling layer 51 is formed, an outer surface of a part of the second dielectric layer 41 in the edge region 112 of the second substrate 11 and the unbonded surface of the second filling layer 51 are also exposed.

In some embodiments, after the first bonding layer is formed, step S402 is performed: The first substrate is thinned to form a first bonded structure. Still referring to FIG. 20, after the first bonding layer 60 is formed, thinning processing is performed on the first substrate 10 to form a first bonded structure 300. Thinning of the first substrate 10 is performed from another surface away from the first dielectric layer 40. There are two main thinning processing manners: grinding (Grinding) and chemical mechanical polishing (CMP). The objective of thinning processing is to thin the first substrate 10 to a target thickness to meet a product miniaturization requirement.

In some embodiments, the material of the first bonding layer 60 is a material with good fluidity and can be well filled in the gap between the first substrate 10 and the second substrate 11, e.g., an underfill (Underfill). The first bonding layer 60 may be applied between the first substrate 10 and the second substrate 11 by employing an adhesive dispensing process.

In this embodiment of the present disclosure, the first bonding layer is applied between the first substrate and the second substrate bonded to each other, so that a support layer can be further formed between the edge regions of the first substrate and the second substrate, to fill and support the edge regions of the first substrate and the second substrate, thereby further improving edge stability of the first bonded structure.

In some embodiments, after the first bonded structure 300 is formed, step S403 continues to be performed: Multiple first bonded structures are bonded to each other to form a second bonded structure. As shown in FIG. 21, FIG. 21 is a schematic structural diagram of a second bonded structure 400 formed after two first bonded structures 300 shown in FIG. 20 are bonded. In some embodiments, before the two first bonded structures 300 are bonded to each other, a first bonding surface is first formed on the thinned surface of the first substrate 10 in the first bonded structure 300. A specific procedure of forming the first bonding surface is the same as that in FIG. 15 and corresponding descriptions thereof. Details are not described herein.

Still referring to FIG. 21, after bonding of the two first bonded structures 300 is completed, that is, after the central regions of the first bonded structures 300 are bonded to each other and the third edge regions of the first bonded structures 300 are bonded to each other, a second bonding layer 61 is filled in a gap between the two first bonded structures 300 to form the second bonded structure 400. The material and a formation method of the second bonding layer 61 are the same as those of the first bonding layer 60. Details are not described herein.

In some embodiments, after the second bonded structure 400 is formed, the thickness of the second substrate 11 is further thinned, and a bonding surface is formed on the surface of the second substrate 11, to implement bonding of multiple second bonded structures 400. For a formation of the bonding surface on the surface of the second substrate 11, refer to the foregoing procedure of forming the second bonding surface. Details are not described herein. After the multiple second bonded structures 400 are bonded to each other, a third bonding layer may be further filled between the bonded structures. A procedure of forming the third bonding layer, and the material thereof are the same as those of the first bonding layer and the second bonding layer.

In some embodiments, the multiple second bonded structures 400 may be further bonded to each other to form a bonded structure with a higher degree of integration.

In some embodiments, before the multiple second bonded structures 400 are further bonded to each other, the method further includes the following: The second bonded structure 400 is thinned. When the second bonded structure 400 is thinned, thinning may be performed on only one side of the second bonded structure 400, or thinning processing may be performed on two sides of the second bonded structure 400. As shown in FIG. 22, FIG. 22 is a schematic structural diagram obtained after thinning processing is performed on two sides of the second bonded structure 400. A fourth dielectric layer 43, a fourth filling layer 53, and a fifth bond pad 703 are separately formed on the thinned surface of the second substrate 11. The fourth dielectric layer 43, the fourth filling layer 53, and the fifth bond pad 703 are configured for bonding between the subsequent multiple second bonded structures 400.

In some embodiments, after the second bonded structure 400 is formed, the method further includes the following: The second bonded structure 400 is singulated by employing a cutting tool. For example, monolithic processing is performed by employing the cutting tool such as a cutting blade or a laser.

In the foregoing embodiment, in a procedure of forming the first bonded structure 300 and forming the second bonded structure 400, on the basis of improving an effect of bonding between substrates by employing filling layers, each bonding layer is further formed in the gap of the bonded structure, to cover and fix an uneven part still existing at the edge of each substrate, so that edge trimming of each bonded structure can be omitted. Because an unbonded part or a part not firmly bonded at the edge of each substrate is fixed by each bonding layer, a problem of edge material chipping does not occur in subsequent thinning and other process processing steps, thereby omitting an edge trimming step and reducing production costs.

In some embodiments, with reference to FIG. 20 and FIG. 23, FIG. 23 is a cross-sectional top view along an A1-A2 direction in FIG. 20. The first substrate 10 includes the first dielectric layer 40 disposed in the central region 101 and the first filling layer 50 disposed in the edge region 102. The first bonding layer 60 is further disposed on a periphery of the first filling layer 50. Multiple first bond pads 70 are disposed in the first dielectric layer 40. The first bond pads 70 may be evenly distributed or unevenly distributed in the first dielectric layer 40. The shape of the first bond pad 70 may be circular, rectangular, or another shape. The outermost edge of the first dielectric layer 40 in the central region 101 to the center of the first substrate 10 has a radial distance R1, the outermost edge of the first filling layer 50 to the center of the central region 101 of the first substrate 10 has a maximum radial distance R2, and the outermost edge of the first bonding layer 60 to the center of the central region 101 of the first substrate 10 has a maximum radial distance R3, where a difference between R3 and R2 is less than a difference between R2 and R1. For example, the first substrate 10 is a 12-inch wafer, the difference between R2 and R1 ranges from 1.5 mm-2.5 mm, the difference between R3 and R2 ranges from 0.1 mm-0.5 mm, that is, a value of R1 ranges from 147 mm to 147.5 mm, a value of R2 ranges from 148.5 mm to 149.5 mm, and a value of R3 is greater than or equal to 150 mm. It may be learned from this that, in this embodiment of the present disclosure, by forming the first filling layer 50, a flat region with a width of 1.5 mm to 2.5 mm can be formed in the edge region 102, thereby improving bonding stability of the edge region of the first substrate 10. For a 0.5 mm non-flat region at the outermost edge, trimming and sealing of the edge of the first substrate 10 may be implemented in a form of filling the first bonding layer, thereby omitting a process of trimming the edge of the first substrate 10, and improving the bonding yield.

An embodiment of the present disclosure further provides a semiconductor structure. As shown in FIG. 7, the semiconductor structure includes a first substrate 10, and the first substrate 10 has a central region 101 and an edge region 102 disposed around the central region 101. In some embodiments, the first substrate 10 may be a wafer or a part of the wafer, the central region 101 may be a region in which a semiconductor device 20 is disposed in the wafer or the part of the wafer, and the edge region 102 may be an edge region in the wafer or the part of the wafer, in which the semiconductor device 20 may not be disposed.

A first dielectric layer 40 is included, the first dielectric layer 40 covers the central region 101 and the edge region 102, and the thickness of the first dielectric layer 40 covering the edge region 102 gradually decreases in a direction away from the central region 101. In other words, the thickness of the first dielectric layer 40 in the edge region 102 is uneven, and the thickness of the first dielectric layer 40 decreases as the edge region 102 is further away from the central region 101.

A first filling layer 50 is included, and the first filling layer 50 is formed above the first dielectric layer 40 in the edge region 102, that is, the first filling layer 50 covers the first dielectric layer 40 in the edge region 102. The surface of the first filling layer 50 is flush with the surface of the first dielectric layer 40 in the central region 101. The “flush” herein may mean that the surfaces of the two are substantially flush or a surface height difference of the two is within a predetermined range.

In some embodiments, another semiconductor structure is further provided. As shown in FIG. 13, the semiconductor structure further includes a second substrate 11, and the second substrate 11 has a central region 111 and an edge region 112 around the central region 111. The second substrate 11 has the same or similar structural feature as the first substrate 10. The central region 111 may be a region in which a semiconductor device 21 is disposed in a wafer or a part of the wafer, and the edge region 112 may be an edge region in the wafer or the part of the wafer, in which the semiconductor device 21 may not be disposed. The semiconductor device 21 and the semiconductor device 20 may be semiconductor devices of the same type or semiconductor devices of different types.

The second dielectric layer 41 is included, the second dielectric layer 41 covers the central region 111 and the edge region 112, and the thickness of the second dielectric layer 41 covering the edge region 112 gradually decreases in a direction away from the central region 111. In other words, the thickness of the second dielectric layer 41 in the edge region 112 is uneven, and the thickness of the second dielectric layer 41 decreases as the edge region 112 is further away from the central region 111.

A second filling layer 51 is included, the second filling layer 51 is formed above the second dielectric layer 41 in the edge region 112, that is, the second filling layer 51 covers the second dielectric layer 41 in the edge region 112. The surface of the second filling layer 51 is flush with the surface of the second dielectric layer 41 in the central region 111. The “flush” herein may mean that the surfaces of the two are substantially flush or a surface height difference of the two is within a predetermined range.

The first dielectric layer 40 in the central region 101 of the first substrate 10 is aligned with and bonded to the second dielectric layer 41 in the central region of the second substrate 11, and the first filling layer 50 is aligned with and bonded to the second filling layer 51 to form the semiconductor structure.

In some embodiments, the semiconductor structure further includes first bond pads. As shown in FIG. 7, an interconnection layer 30 is further disposed in the central region 101 of the first substrate 10, the interconnection layer 30 is connected to the semiconductor device 20, the first bond pad 70 is formed in the first dielectric layer 40, and the first bond pad 70 is connected to the interconnection layer 30 through the first dielectric layer 40. In some embodiments, the first bond pad 70 may not be connected to the interconnection layer 30. The first bond pad 70 is configured for a signal lead-out structure of the interconnection layer 30 in the first dielectric layer 40 in the central region, and a structure subsequently configured for bonding interconnection.

In some embodiments, the semiconductor structure further includes second bond pads. As shown in FIG. 13 to FIG. 18, the second bond pad 71 is aligned with and bonded to the first bond pad 70. The second bond pad 71 is connected to an interconnection layer 31 disposed in the central region 111 of the second substrate 11, and the interconnection layer 31 is connected to the semiconductor device 21. The second bond pad 71 is disposed in the second dielectric layer 41, and is connected to the interconnection layer 31 through the second dielectric layer 41. The first bond pad 70 and the second bond pad 71 bonded to each other in the semiconductor structure implement an electrical connection between the semiconductor device 20 and the semiconductor device 21.

Still referring to FIG. 7 and FIG. 13 to FIG. 18, in some embodiments, the semiconductor structure further includes a via interconnection structure 80 disposed in the first substrate 10 and a via interconnection structure 81 disposed in the second substrate 11. The via interconnection structure 80 is disposed in the central region 101 of the first substrate 10, runs through or partially runs through the first substrate 10, is connected to the interconnection layer 30, and is finally connected to the first bond pad 70. The via interconnection structure 81 is disposed in the central region 111 of the second substrate 11, runs through or partially runs through the second substrate 11, is connected to the interconnection layer 31, and is finally connected to the second bond pad 71.

In some embodiments, the semiconductor structure further includes a first bonding layer, as shown in FIG. 20 to FIG. 23. The first bonding layer 60 is disposed between the first substrate 10 and the second substrate 11 bonded to each other, and the first bonding layer 60 covers at least unbonded surfaces of the first filling layer 50 and the second filling layer 51. In some embodiments, the first bonding layer 60 covers parts of outer edges of the first filling layer 50 and the second filling layer 51. The first bonding layer 60 further covers parts of outer edges of the first dielectric layer 40 and the second dielectric layer 41. In some embodiments, the material of the first bonding layer 60 may be a filling material with fluidity, e.g., an underfill filler.

In some embodiments, as shown in FIG. 20 and FIG. 23, the maximum radial distance from the central region 101 of the first substrate 10 of the semiconductor structure to the center of the central region 101 is R1, the maximum radial distance from the first filling layer 50 to the center of the central region 101 is R2, the maximum radial distance from the first bonding layer 60 to the center of the central region 101 is R3, and the difference between R2 and R1 is greater than the difference between R3 and R2. In some embodiments, the difference between R2 and R1 ranges from 1.5 mm-2.5 mm, and the difference between R3 and R2 ranges from 0.1 mm-0.5 mm.

The quantities of first substrates and second substrates in the semiconductor structure provided in some embodiments may be multiple, e.g., 6, 8, 12, or more.

The semiconductor structure provided in the embodiments of the present disclosure has the first filling layer in the edge region that is flush with the surface of the central region, so that the surface area of a flat region of the edge region can be further increased, and the bonding yield of subsequent surface bonding can be improved.

A person of ordinary skill in the art may understand that the foregoing implementations are specific embodiments for implementing the present disclosure. In actual application, various modifications may be made to the forms and details of the implementations without departing from the spirit and scope of the embodiments of the present disclosure. Any person skilled in the art may make changes and modifications without departing from the spirit and scope of the embodiments of the present disclosure. Therefore, the protection scope of the embodiments of the present disclosure shall be subject to the scope defined by the claims.

1. A manufacturing method for a semiconductor structure, comprising:
providing a first substrate, the first substrate having a central region and an edge region;
forming a first dielectric layer covering the central region and the edge region, a thickness of the first dielectric layer covering the edge region gradually decreasing in a direction away from the central region;
forming a first filling layer covering the first dielectric layer in the edge region; and
planarizing the first filling layer, and forming, on a surface of the first filling layer, a first edge region flush with a surface of the first dielectric layer in the central region.

2. The manufacturing method according to claim 1, further comprising:
providing a second substrate, wherein the second substrate has a central region and an edge region;
forming, on the second substrate, a second dielectric layer covering the central region and the edge region, wherein a thickness of the second dielectric layer covering the edge region gradually decreases in a direction away from the central region;
forming, on the edge region, a second filling layer covering the second dielectric layer;
planarizing the second filling layer, and forming, on a surface of the second filling layer, a second edge region flush with a surface of the second dielectric layer in the central region; and
aligning and bonding the second substrate with and to the first substrate, so that the central region of the first substrate is bonded to the central region of the second substrate, and the first edge region is bonded to the second edge region.

3. The manufacturing method according to claim 2, further comprising performing first edge trimming on the first substrate and the second substrate bonded to each other, to remove a part of the edge region of the first substrate and a part of the edge region of the second substrate, and remove a part of the first edge region and a part of the second edge region; and
thinning the first substrate to form a first bonded structure.

4. The manufacturing method according to claim 3, further comprising bonding a plurality of first bonded structures to each other to form a second bonded structure.

5. The manufacturing method according to claim 4, wherein before the bonding a plurality of first bonded structures to each other to form a second bonded structure, and after the thinning the first substrate, the method further comprises forming a first bonding surface on a surface of the thinned first substrate, and steps of forming the first bonding surface comprise:
depositing, on the surface of the thinned first substrate, a third dielectric layer covering the central region and the edge region, wherein a thickness of the third dielectric layer gradually decreases in the direction away from the central region; and
depositing a third filling layer on the third dielectric layer in the edge region, planarizing the third filling layer, and forming, on a surface of the third filling layer, a third edge region flush with a surface of the third dielectric layer in the central region; and
the bonding a plurality of first bonded structures to each other to form a second bonded structure comprises: bonding central regions of the plurality of first bonded structures to each other, and bonding third edge regions of the plurality of first bonded structures to each other.

6. The manufacturing method according to claim 5, further comprising performing second edge trimming on the second bonded structure to remove a part of the edge region that is in each of the first bonded structures and that is of the second substrate retained after the first edge trimming and a part of the third edge region, wherein a width of the edge region of the second substrate removed in the first edge trimming is the same as a width of the edge region of the second substrate removed in the second edge trimming.

7. The manufacturing method according to claim 5, after the bonding central regions of the plurality of first bonded structures to each other, and bonding third edge regions of the plurality of first bonded structures to each other, further comprising thinning the second substrate to form the second bonded structure.

8. The manufacturing method according to claim 7, further comprising: providing a third substrate, wherein the third substrate has a central region and an edge region;
forming a fourth dielectric layer covering the central region and the edge region, wherein a thickness of the fourth dielectric layer covering the edge region gradually decreases in a direction away from the central region;
forming a fourth filling layer covering the fourth dielectric layer in the edge region;
planarizing the fourth filling layer, and forming, on a surface of the fourth filling layer, a fourth edge region flush with a surface of the fourth dielectric layer in the central region;
forming a second bonding surface on a surface of the thinned second bonded structure; and
aligning and bonding the third substrate with and to the second bonded structure, so that the central region of the third substrate and the fourth edge region are bonded to the second bonding surface.

9. The manufacturing method according to claim 2, after the aligning and bonding the second substrate with and to the first substrate, further comprising:
filling a first bonding layer between the first substrate and the second substrate, wherein the first bonding layer covers at least the first dielectric layer, the second dielectric layer, and unbonded surfaces of the first filling layer and the second filling layer.

10. The manufacturing method according to claim 9, wherein after the first bonding layer is formed, the first substrate is thinned to form a first bonded structure.

11. The manufacturing method according to claim 10, further comprising bonding a plurality of first bonded structures to each other to form a second bonded structure.

12. The manufacturing method according to claim 11, wherein before the bonding a plurality of first bonded structures to each other to form a second bonded structure, and after the thinning the first substrate, the method further comprises forming a first bonding surface on a surface of a thinned first substrate, and steps of forming the first bonding surface comprise:
depositing, on the surface of the thinned first substrate, a third dielectric layer covering the central region and the edge region, wherein a thickness of the third dielectric layer gradually decreases in the direction away from the central region; and
depositing a third filling layer on the third dielectric layer in the edge region, planarizing the third filling layer, and forming, on a surface of the third filling layer, a third edge region flush with a surface of the third dielectric layer in the central region; and
the bonding a plurality of first bonded structures to each other to form a second bonded structure comprises: bonding central regions of the plurality of first bonded structures to each other, and bonding third edge regions of the plurality of first bonded structures to each other.

13. The manufacturing method according to claim 12, wherein after the central regions of the plurality of first bonded structures are bonded to each other and the third edge regions of the plurality of first bonded structures are bonded to each other, a second bonding layer is filled between the first bonded structures.

14. The manufacturing method according to any one of claim 1, after the first dielectric layer covering the central region and the edge region is formed, and before the first filling layer covering the first dielectric layer in the edge region is formed, further comprising:
forming first bond pads in the first dielectric layer in the central region; and
planarizing the first dielectric layer after the first bond pads are formed, so that a surface of each of the first bond pads is flush with the surface of the first dielectric layer.

15. The manufacturing method according to any one of claim 1, after the first edge region is formed, further comprising:
forming first bond pads in the first dielectric layer, wherein a surface of each of the first bond pads is flush with the surface of the first dielectric layer.

16. A semiconductor structure, comprising:
a first substrate, the first substrate having a central region and an edge region;
a first dielectric layer, the first dielectric layer covering the central region and the edge region, and a thickness of the first dielectric layer covering the edge region gradually decreasing in a direction away from the central region; and
a first filling layer, the first filling layer being formed above the first dielectric layer in the edge region, and a surface of the first filling layer being flush with a surface of the first dielectric layer in the central region.

17. The semiconductor structure according to claim 16, further comprising:
a second substrate, wherein the second substrate has a central region and an edge region;
a second dielectric layer, wherein the second dielectric layer covers the central region and the edge region of the second substrate, and a thickness of the second dielectric layer covering the edge region gradually decreases in a direction away from the central region; and
a second filling layer, wherein the second filling layer is formed above the second dielectric layer in the edge region, and a surface of the second filling layer is flush with a surface of the second dielectric layer in the central region; and
the first dielectric layer in the central region of the first substrate is aligned with and bonded to the second dielectric layer in the central region of the second substrate, and the first filling layer is aligned with and bonded to the second filling layer.

18. The semiconductor structure according to claim 17, further comprising a first bonding layer, wherein the first bonding layer is disposed between the first substrate and the second substrate bonded to each other, and the first bonding layer covers at least unbonded surfaces of the first filling layer and the second filling layer.

19. The semiconductor structure according to claim 18, wherein a maximum radial distance from the central region to a center of the central region is R1, a maximum radial distance from the first filling layer to the center of the central region is R2, a maximum radial distance from the first bonding layer to the center of the central region is R3, and a difference between R2 and R1 is greater than a difference between R3 and R2.

20. The manufacturing method according to claim 1, after the first edge region is formed, the first dielectric layer is patterned, and a first bonding material layer is formed in the first dielectric layer, planarizing the first bonding material layer to form first bonding pads that are isolated from each other and that have surfaces exposed to the first dielectric layer are formed in the first dielectric layer, wherein surfaces of the first bonding pads are coplanar with a surface of the first dielectric layer.
